(19) United States
(12) Patent Application Publication
(10) Pub. No.: US 2023/0099647 A1
(43) Pub. Date: Mar. 30, 2023

(54) ELECTRONIC APPARATUS

(71) Applicant: Corning Incorporated, Corning, NY (US)

(72) Inventors: Sean Matthew Garner, Elmira, NY (US); David Andrew Pastel, Horseheads, NY (US); Dean Michael Thelen, Addison, NY (US)

(21) Appl. No.: 17/905,373

(22) PCT Filed: Feb. 25, 2021
(86) PCT No.: PCT/US2021/019551

§ 371 Date: Aug. 31, 2022

Related U.S. Application Data
(60) Provisional application No. 62/990,652, filed on Mar. 17, 2020.

(51) Int. Cl. H01L 25/16; H01L 33/62

(52) U.S. Cl. CPC H01L 25/167; H01L 33/62

(57) ABSTRACT

An electronic apparatus includes a substrate including a first major surface, a second major surface, and an edge surface. The edge surface includes a radius of curvature extending between the first major surface and the second major surface. The electronic apparatus includes an opto-electronic device positioned on the first major surface. The electronic apparatus includes an electrical component positioned on the second major surface. The electronic apparatus includes a first electrically-conductive trace attached to the edge surface. The first electrically-conductive trace electrically connects a first portion of the opto-electronic device to the electrical component and defines a first current path. The electronic apparatus includes a second electrically-conductive trace extending through an opening in the substrate. The second electrically-conductive trace electrically connects a second portion of the opto-electronic device to the electrical component and defines a second current path different than the first current path.

### CROSS-REFERENCE TO RELATED APPLICATIONS

This application claims the benefit of priority under 35 U.S.C. § 119 of U.S. Provisional Application Serial No. 62/990,652 filed on Mar. 17, 2020, the content of which is relied upon and incorporated herein by reference in its entirety.

### FIELD

The present disclosure relates generally to methods for manufacturing an electronic apparatus and, more particularly, to methods for manufacturing an electronic apparatus comprising an electrically-conductive trace.

### BACKGROUND

It is known to fabricate an opto-electronic device on a substrate. The opto-electronic device can be positioned on a first major surface of the substrate and an electrical component can be positioned on a second major surface of the substrate. An electrically-conductive trace can electrically connect the opto-electronic device and the electrical component. However, depending on the geometry of the substrate, connecting the electrically-conductive trace to the opto-electronic device and the electrical component can lead to a shortened lifespan of the opto-electronic device and inconsistent electric current transmission.

### SUMMARY

The following presents a simplified summary of the disclosure to provide a basic understanding of some embodiments described in the detailed description.

In some embodiments, an electronic apparatus can comprise an opto-electronic device positioned on a first major surface of a substrate, and an electrical component positioned on a second major surface of the substrate. The electronic apparatus can comprise a first electrically-conductive trace that extends between the first major surface and the second major surface to electrically connect the opto-electronic device and the electronic apparatus. In some embodiments, the substrate may comprise an edge surface that comprises a chamfered shape. The first electrically-conductive trace can be positioned on the edge surface while extending between the first major surface and the second major surface such that a length of the first electrically-conductive trace can be reduced as compared to a substrate comprising a non-chamfered edge surface. Further, an opening can be formed in the substrate between the first major surface and the second major surface, wherein a second electrically-conductive trace can extend through the opening. The first electrically-conductive trace and the second electrically-conductive trace can comprise different cross-sectional areas such that one of the electrically-conductive traces may be well-suited for transmitting data signals to the opto-electronic device, while the other of the electrically-conductive traces may be well-suited for transmitting power to the opto-electronic device. Further, the first electrically-conductive trace can overlap an electrically-conductive feed line, which can reduce current crowding

In accordance with some embodiments, an electronic apparatus can comprise a substrate that can comprise a first major surface, a second major surface, and an edge surface extending between the first major surface and the second major surface. The edge surface can comprise a radius of curvature extending between the first major surface and the second major surface. The electronic apparatus can comprise an opto-electronic device positioned on the first major surface. The electronic apparatus can comprise an electrical component positioned on the second major surface. The electronic apparatus can comprise a first electrically-conductive trace attached to the edge surface and extending between the first major surface and the second major surface. The first electrically-conductive trace can electrically connect a first portion of the opto-electronic device to the electrical component and define a first current path. The electronic apparatus can comprise a second electrically-conductive trace extending through an opening in the substrate between the first major surface and the second major surface. The second electrically-conductive trace can electrically connect a second portion of the opto-electronic device to the electrical component and define a second current path different than the first current path.

In some embodiments, the electronic apparatus can comprise an electrically-conductive feed line extending between a first end that may be electrically connected to the opto-electronic device and a second end that can comprise a first width.

In some embodiments, the first electrically-conductive trace can extend between a first end that can be electrically connected to the electrically-conductive feed line and a second end that can be electrically connected to the electrical component.

In some embodiments, the first end of the first electrically-conductive trace can overlap the second end of the electrically-conductive feed line such that the second end of the electrically-conductive feed line can be positioned between the substrate and the first end of the first electrically-conductive trace. The first end of the first electrically-conductive trace can comprise a second width that is less than or equal to the first width.

In some embodiments, the second electrically-conductive trace can extend through a second opening in the second end of the electrically-conductive feed line.

In some embodiments, the second electrically-conductive trace can extend between a first end that can be received within the second opening of the electrically-conductive feed line and a second end that can be electrically connected to the electrical component.

In some embodiments, the first end of the second electrically-conductive trace can comprise a diameter that can be less than the first width.

In some embodiments, a first cross-sectional area of the first electrically-conductive trace can be less than a second cross-sectional area of the second electrically-conductive trace.

In some embodiments, the opto-electronic device can comprise a micro light-emitting diode.

In accordance with some embodiments, an electronic apparatus can comprise a substrate that can comprise a first major surface, a second major surface, and an edge surface extending between the first major surface and the second major surface. The edge surface can comprise a radius of curvature extending between the first major surface and the second major surface. The electronic apparatus can comprise an opto-electronic device positioned on the first major surface. The electronic apparatus can comprise an electrical component positioned on the second major surface. The electronic apparatus can comprise an electrically-conductive feed line that can extend between a first end that can be electrically connected to the opto-electronic device and a second end that can comprise a first width. The electronic apparatus can comprise a first electrically-conductive trace that can be attached to the edge surface and can extend between the first major surface and the second major surface. The first electrically-conductive trace can extend between a first end that can be electrically connected to the electrically-conductive feed line and a second end that can be electrically connected to the electrical component. The first end of the first electrically-conductive trace can overlap the second end of the electrically-conductive feed line such that the second end of the electrically-conductive feed line can be positioned between the substrate and the first end of the first electrically-conductive trace. The first end of the first electrically-conductive trace can comprise a second width that can be less than or equal to the first width.

In some embodiments, a bulk resistivity of the electrically-conductive feed line can be different than a bulk resistivity of the first electrically-conductive trace.

In some embodiments, the radius of curvature can comprise a first radius of curvature between the first major surface and the edge surface.

In some embodiments, a first portion of the second end of the electrically-conductive feed line can be covered by the first end of the first electrically-conductive trace, and a second portion of the second end of the electrically-conductive feed line can be uncovered.

In some embodiments, the opto-electronic device can comprise a micro light-emitting diode.

In accordance with some embodiments, an electronic apparatus can comprise a substrate that can comprise a first major surface, a second major surface, and an edge surface extending between the first major surface and the second major surface. The edge surface can comprise a radius of curvature extending between the first major surface and the second major surface. The electronic apparatus can comprise an opto-electronic device positioned on the first major surface. The electronic apparatus can comprise an electrical component positioned on the second major surface. The electronic apparatus can comprise an electrically-conductive feed line that can extend between a first end that can be electrically connected to the opto-electronic device and a second end that can comprise a first width. The electronic apparatus can comprise a second electrically-conductive trace that can extend through an opening in the substrate between the first major surface and the second major surface and a second opening in the second end of the electrically-conductive feed line. The second electrically-conductive trace can extend between a first end that can be received within the second opening of the electrically-conductive feed line and a second end that can be electrically connected to the electrical component. The first end of the second electrically-conductive trace can comprise a diameter that is less than the first width.

In some embodiments, the first end of the second electrically-conductive trace can be surrounded by the second end of the electrically-conductive feed line.

In some embodiments, a bulk resistivity of the electrically-conductive feed line can be different than a bulk resistivity of the second electrically-conductive trace.

In some embodiments, the opto-electronic device can comprise a micro light-emitting diode.

Additional features and advantages of the embodiments disclosed herein will be set forth in the detailed description that follows, and in part will be clear to those skilled in the art from that description or recognized by practicing the embodiments described herein, including the detailed description which follows, the claims, as well as the appended drawings. It is to be understood that both the foregoing general description and the following detailed description present embodiments intended to provide an overview or framework for understanding the nature and character of the embodiments disclosed herein. The accompanying drawings are included to provide further understanding and are incorporated into and constitute a part of this specification. The drawings illustrate various embodiments of the disclosure, and together with the description explain the principles and operations thereof.

### BRIEF DESCRIPTION OF THE DRAWINGS

These and other features, embodiments and advantages are better understood when the following detailed description is read with reference to the accompanying drawings, in which:

FIG. 1 schematically illustrates a top view of example embodiments of an electronic apparatus in accordance with embodiments of the disclosure;

FIG. 2 illustrates a cross-sectional view of the electronic apparatus along line 2-2 of FIG. 1 in accordance with embodiments of the disclosure;

FIG. 3 illustrates a top view of example embodiments of an electrically-conductive trace and an electrically-conductive feed line along line 3-3 of FIG. 2 in accordance with embodiments of the disclosure;

FIG. 4 illustrates a cross-sectional view of a second electrically-conductive trace extending through an opening in a substrate along line 4-4 of FIG. 1 in accordance with embodiments of the disclosure; and

FIG. 5 illustrates a top view of example embodiments of the second electrically-conductive trace along line 5-5 of FIG. 4 in accordance with embodiments of the disclosure.

### DETAILED DESCRIPTION

Embodiments will now be described more fully hereinafter with reference to the accompanying drawings in which example embodiments are shown. Whenever possible, the same reference numerals are used throughout the drawings to referto the same or like parts. However, this disclosure may be embodied in many different forms and should not be construed as limited to the embodiments set forth herein.

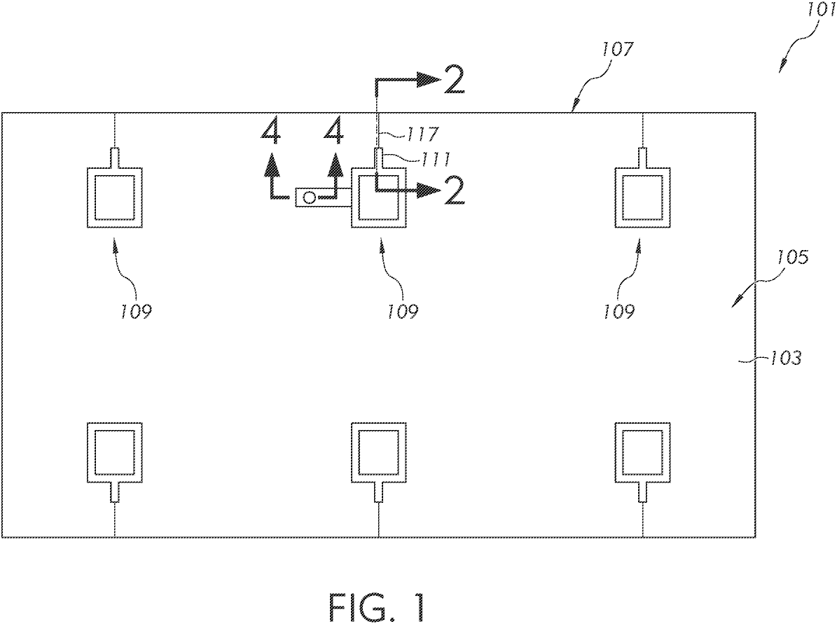

The present disclosure relates to an electronic apparatus. FIG. 1 is a schematic top-down plan view of an electronic apparatus 101 in accordance with embodiments of the disclosure. The electronic apparatus 101 can comprise a substrate 103. In some embodiments, the substrate 103 may comprise glass (e.g., a glass substrate), for example, one or more of soda-lime glass, borosilicate glass, alumino-borosilicate glass, alkali-containing glass, alkali-free glass, aluminosilicate, borosilicate, boroaluminosilicate, silicate, glass-ceramic, or other materials comprising glass. In some embodiments, the substrate 103 can comprise one or more of lithium fluoride (LiF), magnesium fluoride (MgF₂), calcium fluoride (CaF₂), barium fluoride (BaF₂), sapphire (Al₂O₃), zinc selenide (ZnSe), germanium (Ge) or other materials. The substrate 103 can alternatively comprise a ceramic, polymer, composite, metal, multi-layer stack, or a composite of materials. In some embodiments, the substrate 103 (e.g., comprising glass or other optical or non-optical materials) may be used in various display and non-display applications, for example, liquid crystal displays (LCDs), electrophoretic displays (EPD), organic light emitting diode displays (OLEDs), plasma display panels (PDPs), microLED displays, miniLED displays, organic light emitting diode lighting, light emitting diode lighting, augmented reality (AR), virtual reality (VR), touch sensors, photovoltaics, or other applications. The substrate 103 can comprise several shapes, for example, square shapes, rectangular shapes, hexagonal shapes, irregular shapes, etc.

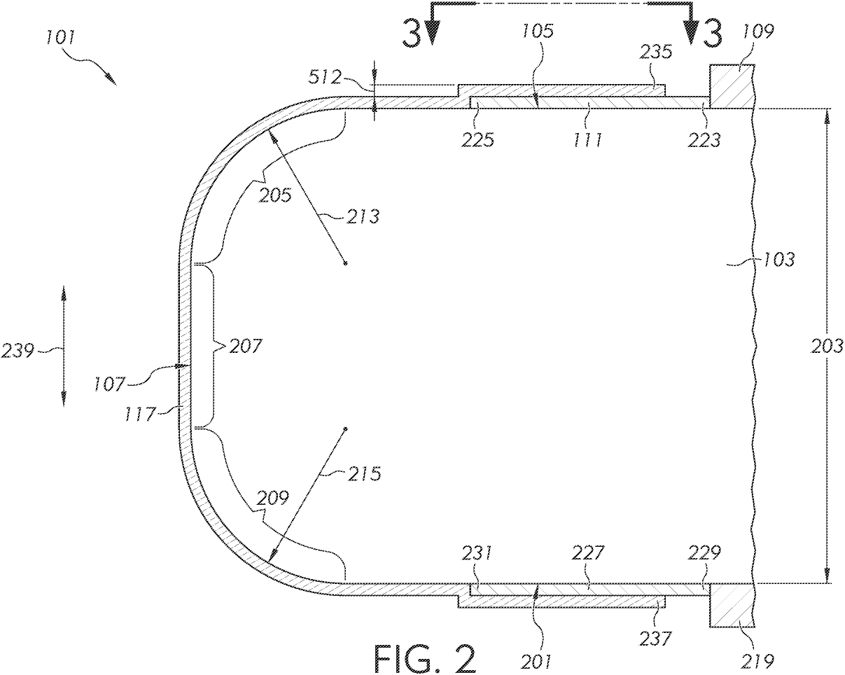

Referring to FIGS. 1-2, FIG. 2 illustrates a sectional view of the electronic apparatus 101 along line 2-2 of FIG. 1. In some embodiments, the substrate 103 can comprise a first major surface 105, a second major surface 201, and an edge surface 107. The edge surface 107 can extend between the first major surface 105 and the second major surface 201. In some embodiments, the first major surface 105 and the second major surface 201 can face opposite directions and may define a thickness 203 (e.g., average thickness) of the substrate 103 extending in a direction normal to at least one of the first major surface 105 or the second major surface 201. For example, the thickness 203 of the substrate 103 can be less than or equal to about 2 millimeters (mm), less than or equal to about 1 mm, less than or equal to about 0.5 mm, for example, less than or equal to about 300 micrometers (µm), less than or equal to about 200 µm, or less than or equal to about 100 µm, although other thicknesses may be provided in further embodiments. In some embodiments, the first major surface 105 and the second major surface 201 may be substantially planar, and may extend substantially parallel to one another, although non-planar and/or non-parallel configurations may be provided in further embodiments. In some embodiments, the edge surface 107 may form an outermost perimeter of the substrate 103 and may extend about the perimeter of the substrate 103.

In some embodiments, the edge surface 107 may comprise a non-planar shape that extends between the first major surface 105 and the second major surface 201. The edge surface 107 can comprise one or more edge portions, for example, a first edge portion 205, a second edge portion207, and a third edge portion 209. The first edge portion 205 may be non-planar and the second edge portion 207 can be non-planar. The first edge portion 205 can extend between the first major surface 105 and the second edge portion 207, wherein one end of the first edge portion 205 can be attached to the first major surface 105 and an opposing end of the first edge portion 205 can be attached to the second edge portion 207. In some embodiments, the first edge portion 205 can comprise a rounded shape with a first radius of curvature 213. In some embodiments, the first radius of curvature 213 can be less than about 100 µm, less than about 50 µm, less than about 20 µm, less than about 10 µm, or less than about 5 µm. In some embodiments, the first edge portion 205 can comprise a substantially flat, planar shape that extends between the first major surface 105 and the second edge portion 207. The first edge portion 205 can also comprise a non-planar surface with a complex non-constant radius. When the first edge portion 205 comprises the substantially flat, planar shape, the first edge portion 205 can comprise a first radius of curvature at a junction between the first edge portion 205 and the first major surface 105 (e.g., wherein the first edge portion 205 comprises a rounded shape at the first major surface 105), and a second radius of curvature at a junction between the first edge portion 205 and the second edge portion 207 (e.g., wherein the first edge portion 205 comprises a rounded shape at the end adjacent to the second edge portion 207). In some embodiments, the third edge portion 209 can extend between the second major surface 201 and the second edge portion 207, wherein one end of the third edge portion 209 can be attached to the second major surface 201 and an opposing end of the third edge portion 209 can be attached to the second edge portion 207. In some embodiments, the third edge portion 209 can comprise a rounded shape with a second radius of curvature 215. In some embodiments, the second radius of curvature 215 can be greater than about 1% of the thickness 203 of the substrate 103, greater than about 5% of the thickness 203 of the substrate 103, greater than about 10% of the thickness 203 of the substrate 103, greater than about 20% of the thickness 203 of the substrate 103, greater than about 50% of the thickness 203 of the substrate 103, or greater than about 100% of the thickness 203 of the substrate 103. The third edge portion 209 can also comprise a non-planar surface with a complex non-constant radius. The third edge portion 209 can comprise a different shape than the first edge portion 205.

In some embodiments, the third edge portion 209 can comprise a substantially flat, planar shape that extends between the second major surface 201 and the second edge portion 207. When the third edge portion 209 comprises a substantially flat, planar shape, the third edge portion 209 can comprise a first radius of curvature at a junction between the third edge portion 209 and the second major surface 201 (e.g., wherein the third edge portion 209 comprises a rounded shape at the second major surface 201), and a second radius of curvature at a junction between the third edge portion 209 and the second edge portion 207 (e.g., wherein the third edge portion 209 comprises a rounded shape at the end adjacent to the second edge portion 207). In some embodiments, the second edge portion 207 can extend between the first edge portion 205 and the third edge portion 209. In some embodiments, the second edge portion 207 can comprise a substantially planar shape, for example, by extending substantially perpendicularly relative to the first major surface 105 and the second major surface 201. The second edge portion 207 can also comprise a non-planar surface with a complex non-constant radius.

In some embodiments, the electronic apparatus 101 can comprise one or more opto-electronic devices positioned on the first major surface 105. For example, in some embodiments, an opto-electronic device 109 can be positioned on the first major surface 105. As used herein, the term “positioned on” can comprise direct contact between a structure (e.g., the electronic apparatus 101, for example) and a surface of the substrate 103. In addition, in some embodiments, the term “positioned on” can comprise indirect contact between a structure (e.g., the electronic apparatus 101, for example) and a surface of the substrate 103, for example, when an intermediate structure is located between the structure and the surface of the substrate 103. As such, by being positioned on a surface of the substrate 103, the structure can be near (e.g., or proximate) the surface of the substrate 103 while being in direct contact or not in contact with the surface of the substrate 103. The opto-electronic device 109 can comprise several types of electronic devices that can generate and/or emit light or control the emission, transmission, and/or reflection of light. In some embodiments, the opto-electronic device 109 can comprise, for example, a micro light-emitting diode (microLEDs), an organic light-emitting diode (OLEDs), or other types of light-emitting diodes. In some embodiments, the opto-electronic device 109 can comprise a liquid crystal, electrophoretic, or micro-mirror structure. In some embodiments, the microLEDs can comprise an inorganic LED structure with a linear dimension of less than about 200 µm. In some embodiments, the LED structure can comprise a linear dimension of less than about 100 µm, less than about 50 µm, or less than about 20 µm. By being positioned on the first major surface 105, the opto-electronic device 109 may or may not be in contact with the first major surface 105. For example, in some embodiments, the opto-electronic device 109 may be directly connected to and in contact with the first major surface 105. In some embodiments, the opto-electronic device 109 may not be in contact with the first major surface 105 while still being connected to the first major surface 105, for example, with one or more intervening layers or structures between the opto-electronic device 109 and the first major surface 105 (e.g., conductive materials, dielectric materials, semiconductor materials, solder balls, etc.). Additional electronic structures may also exist on the first major surface 105 such as thin film transistors, micro-driver ICs, resistors, capacitors, and conductor lines.

In some embodiments, the electronic apparatus 101 can comprise an electrical component 219 positioned on the second major surface 201. The electrical component 219 can comprise, for example, an integrated circuit or a driver circuit for the opto-electronic device 109. These integrated circuits or driver circuits may also be placed on a separate printed circuit board that may be electrically connected to the second major surface 201. The electrical component 219 positioned on the second major surface 201 can also comprise a conductor line, solder ball, or other structure for forming electrical connections with separate components. By being positioned on the second major surface 201, the electrical component 219 may or may not be in contact with the second major surface 201. For example, in some embodiments, the electrical component 219 may be directly connected to and in contact with the second major surface 201. In some embodiments, the electrical component 219 may not be in contact with the second major surface 201 while still being connected to the second major surface 201, for example, with one or more intervening layers or structures between the electrical component 219 and the second major surface 201 (e.g., conductive materials, dielectric materials, semiconductor materials, solder balls, etc.).

In some embodiments, the electronic apparatus 101 can comprise an electrically-conductive feed line 111 that can be electrically connected to the opto-electronic device 109. The electrical connection does not need to be direct but can go through intermediate electrical elements such as thin film transistors, capacitors, resistors, or other conductor elements. For example, the electrically-conductive feed line 111 can be positioned on the first major surface 105. The electrically-conductive feed line 111 can comprise an electrically-conductive material through which electric current can be conducted. For example, in some embodiments, the electrically-conductive feed line 111 can comprise a conductive metal, such as one or more of aluminum (Al), copper (Cu), gold (Au), nickel (Ni), silver (Ag), molybdenum (Mo), indium tin oxide (ITO), titania (Ti) or tin (Sn) or other materials such as carbon nano-tubes (CNT) and conductive pastes. By being positioned on the first major surface 105, the electrically-conductive feed line 111 may or may not be in contact with the first major surface 105. For example, in some embodiments, the electrically-conductive feed line 111 may be directly connected to and in contact with the first major surface 105. In some embodiments, the electrically-conductive feed line 111 may not be in contact with the first major surface 105 while still being connected to the first major surface 105, for example, with one or more intervening layers or structures between the electrically-conductive feed line 111 and the first major surface 105 (e.g., conductive materials, dielectric materials, semiconductor materials, solder balls, etc.). In some embodiments, the electrically-conductive feed line 111 can be positioned exclusively on the first major surface 105 (e.g., and not on the second major surface 201 and/or the edge surface 107). For example, in the embodiments of FIGS. 1-2, the electrically-conductive feed line 111 is illustrated as being positioned on the first major surface 105. However, in some embodiments, the electrically-conductivefeedline 111 can be positioned at least partially on both the first major surface 105 and the edge surface 107. In this case, the electrically-conductive feed line 111 can vary in width, thickness, or cross-sectional shape on the different surfaces.

In some embodiments, the electrically-conductive feed line 111 can extend between a first end 223 that may be electrically connected to the opto-electronic device 109 and a second end 225. For example, the first end 223 can be electrically connected to the opto-electronic device 109 such that the electrically-conductive feed line 111 can conduct electric current to and/or from the opto-electronic device 109 or alter the electrical voltage at the opto-electronic device 109. In some embodiments, the electrically-conductive feed line 111 can transmit data signals to the opto-electronic device 109 such that the data signals can control the operation of the opto-electronic device 109. In some embodiments, the electrically-conductive feed line 111 can transmit power to the opto-electronic device 109 such that the opto-electronic device 109 can be powered through the electrically-conductive feed line 111. In some embodiments, the electrically-conductive feed line 111 can be electrically connected to a plurality of opto-electronic devices (e.g, more than one of the opto-electronic device 109), such that the data signals and/or power can be transmitted to the plurality of opto-electronic devices. In some embodiments, each opto-electronic device 109 can be electrically connected to a separate electrically-conductive feed line 111.

In some embodiments, the electronic apparatus 101 can comprise a second electrically-conductive feed line 227 that can be electrically connected to the electrical component 219. For example, the second electrically-conductive feed line 227 can be positioned on the second major surface 201. The second electrically-conductive feed line 227 can comprise an electrically-conductive material through which electric current can be conducted. For example, in some embodiments, the second electrically-conductive feed line 227 can be similar to the electrically-conductive feed line 111 and can comprise a conductive metal, such as one or more of aluminum (Al), copper (Cu), gold (Au), nickel (Ni), silver (Ag), molybdenum (Mo), indium tin oxide (ITO), titania (Ti), or tin (Sn). By being positioned on the second major surface 201, the second electrically-conductive feed line 227 may or may not be in contact with the second major surface 201. For example, in some embodiments, the second electrically-conductive feed line 227 may be directly connected to and in contact with the second major surface 201. In some embodiments, the electrically-conductive feed line 111 may not be in contact with the second major surface 201 while still being connected to the second major surface 201, for example, with one or more intervening layers or structures between the second electrically-conductive feed line 227 and the second major surface 201 (e.g., conductive materials, dielectric materials, semiconductor materials, solder balls, etc.). In some embodiments, the second electrically-conductive feed line 227 can be positioned exclusively on the second major surface 201 (e.g., and not on the first major surface 105 and/or the edge surface 107). For example, in the embodiments of FIG. 2, the second electrically-conductive feed line 227 is illustrated as being positioned on the second major surface 201. However, in some embodiments, the second electrically-conductive feed line 227 can be positioned at least partially on both the second major surface 201 and the edge surface 107. In some embodiments, the second electrically-conductive feed line 227 can vary in width, thickness, or cross-sectional shape on the different surfaces.

In some embodiments, the second electrically-conductive feed line 227 can extend between a first end 229 that may be electrically connected to the electrical component 219 and a second end 231. For example, the first end 229 can be electrically connected to the electrical component 219 such that the second electrically-conductive feed line 227 can conduct electric current to and/or from the electrical component 219 or alter the electrical voltage at the electrical component 219. In some embodiments, the second electrically-conductive feed line 227 can transmit data signals from the electrical component 219 and to the opto-electronic device 109, such that the data signals can control the operation of the opto-electronic device 109. In some embodiments, the second electrically-conductive feed line 227 can transmit power from the electrical component 219 and to the opto-electronic device 109, such that the opto-electronic device 109 can be powered through the second electrically-conductive feed line 227. In some embodiments, the second electrically-conductive feed line 227 can be electrically connected to a plurality of electrical components (e.g., more than one of the electrical component 219), such that the data signals and/or power can be transmitted to one or more of the opto-electronic devices.

In some embodiments, the electronic apparatus 101 can comprise one or more electrically-conductive traces, for example, a first electrically-conductive trace 117 (e.g., illustrated in FIGS. 1-2). As used herein, the terms “line” (e.g., the second electrically-conductive feed line 227, for example) and “trace” (e.g., the first electrically-conductive trace 117, for example) can refer to an electrically conductive material that can transmit electrical current. The first electrically-conductive trace 117 can extend between a first end 235 that may be electrically connected to the electrically-conductive feed line 111 and a second end 237 that may be electrically connected to the electrical component 219 through the second electrically-conductive feed line 227. In some embodiments, the first electrically-conductive trace 117 can be attached to the edge surface 107 and can extend between the first major surface 105 and the second major surface 201. As used herein, the term “attached to” can comprise direct attachment and direct contact between a structure (e.g., the first electrically-conductive trace 117, for example) and a surface (e.g, the edge surface 107) of the substrate 103. In addition, in some embodiments, the term “attached to” can comprise indirect attachment and non-contact between a structure (e.g, the first electrically-conductive trace 117, for example) and a surface of the substrate 103, for example, when an intermediate structure is located between the structure and the surface of the substrate 103. As such, by being attached to a surface of the substrate 103, the structure can be near (e.g., or proximate) the surface of the substrate 103 while being in direct contact or not in contact with the surface of the substrate 103. In some embodiments, the first electrically-conductive trace 117 can be positioned on the first major surface 105, the first edge portion 205, the second edge portion 207, the third edge portion 209, and the second major surface 201. By being positioned on the first major surface 105, the first edge portion 205, the second edge portion 207, the third edge portion 209, and the second major surface 201, the first electrically-conductive trace 117 may or may not be in contact with the first major surface 105, the first edge portion 205, the second edge portion 207, the third edge portion 209, and the second major surface 201. Rather, in some embodiments, one or more intervening structures (e.g., electrical insulators, adhesives, etc.) may be positioned between the first electrically-conductive trace 117 and the first major surface 105, the first edge portion 205, the second edge portion 207, the third edge portion 209, and the second major surface 201. In some embodiments, one or more structures can be positioned over the first electrically-conductive trace 117 to protect the first electrically-conductive trace 117 from damage and/or to electrically insulate the first electrically-conductive trace 117. The first electrically-conductive trace 117 can comprise an electrically-conductive material through which electric current can be conducted. For example, in some embodiments, the first electrically-conductive trace 117 can comprise a conductive metal, such as one or more of aluminum (Al), copper (Cu), gold (Au), nickel (Ni), silver (Ag), molybdenum (Mo), indium tin oxide (ITO), titania (Ti), or tin (Sn) or other materials such as carbon nano-tubes (CNT) and conductive pastes. In some embodiments, intermediate layers may exist between the first electrically-conductive trace 117 and the electrically-conductive feed line 111 and/or the second electrically-conductive feed line 227.

In some embodiments, by being electrically connected to the second electrically-conductive feed line 227 (e.g., due to the second end 237 of the first electrically-conductive trace 117 being electrically connected to the second end 231 of the second electrically-conductive feed line 227), the first electrically-conductive trace 117 can receive electric current from the second electrically-conductive feed line 227. In some embodiments, the first electrically-conductive trace 117 can receive data signals and/or power from the second electrically-conductive feed line 227. In some embodiments, by being electrically connected to the electrically-conductive feed line 111 (e.g., due to the first end 235 of the first electrically-conductive trace 117 being electrically connected to the second end 225 of the electrically-conductive feed line 111), the first electrically-conductive trace 117 can deliver electric current to the electrically-conductive feed line 111. For example, the first electrically-conductive trace 117 can electrically connect a first portion of the opto-electronic device 109 to the electrical component 219 and can define a first current path 239. The first current path 239 (e.g., illustrated schematically in FIG. 2 with an arrow) can represent a path through which electric current can travel between the opto-electronic device 109 and the electrical component 219. For example, in some embodiments, the first current path 239 can be defined from the electrical component 219, through the second electrically-conductive feed line 227, through the first electrically-conductive trace 117, through the electrically-conductive feed line 111, and to the opto-electronic device 109.

The first electrically-conductive trace 117 can be applied to one or more of the edge surface 107, the first major surface 105, the second major surface 201, the second end 225 of the electrically-conductive feed line 111, or the second end 231 of the second electrically-conductive feed line 227 in several ways. For example, in some embodiments, the first electrically-conductive trace 117 can comprise a printed, electrically-conductive ink that can be printed onto the edge surface 107, the first major surface 105, the second major surface 201, the second end 225 of the electrically-conductive feed line 111, and/or the second end 231 of the second electrically-conductive feed line 227. In some embodiments, the first electrically-conductive trace 117 can comprise an electrically-conductive sputtered metal that can be applied via a sputtering process. For example, an electrically insulating coating can be deposited on the edge surface 107, the first major surface 105, the second major surface 201, wherein the electrically insulating coating may be patterned to form a channel. The first electrically-conductive trace 117 (e.g., comprising the electrically-conductive sputtered metal) can be deposited within the channel and can electrically connect the electrically-conductive feed line 111 and the second electrically-conductive feed line 227. In some embodiments, the first electrically-conductive trace 117 can be formed by an electroless plating process, wherein a catalyst can be exposed to an electroless plating solution to form the first electrically-conductive trace 117 within the channel. In some embodiments, the first electrically-conductive trace 117 can be formed by other vacuum deposition, solution coating electroplating processes, or a combination of those described above to form a multi-layer structure or composite. In some embodiments, the first electrically-conductive trace 117 can be patterned by printing, etching photolithographic, or other methods. While progressing from the first major surface 105 to the second major surface 201, the first electrically-conductive trace 117 can vary in width, thickness, cross-sectional area, and composition.

In some embodiments, the first electrically-conductive trace 117 can at least partially overlap the electrically-conductive feed line 111 and/or the second electrically-conductive feed line 227. For example, focusing on the electrical connection between the firstelectrically-conductivetrace 117 and the electrically-conductive feed line 111, in some embodiments, the first end 235 of the first electrically-conductive trace 117 can overlap the second end 225 of the electrically-conductive feed line 111 such that the second end 225 of the electrically-conductive feed line 111 can be positioned between the substrate 103 and the first end 235 of the first electrically-conductive trace 117. For example, at a location where the first end 235 of the first electrically-conductive trace 117 overlaps the second end 225 of the electrically-conductive feed line 111, the first end 235 of the first electrically-conductive trace 117 may not be in contact with the first major surface 105, but, rather, may be spaced apart from the first major surface 105 with the electrically-conductive feed line 111 positioned in between. In some embodiments, the second end 237 of the first electrically-conductive trace 117 can be electrically connected to the second electrically-conductive feed line 227 in a similar manner as the attachment of the first electrically-conductive trace 117 and the electrically-conductive feed line 111. For example, at a location where the second end 237 of the first electrically-conductive trace 117 overlaps the second end 231 of the second electrically-conductive feed line 227, the second end 237 of the first electrically-conductive trace 117 may not be in contact with the second major surface 201, but, rather, may be spaced apart from the second major surface 201 with the second electrically-conductive feed line 227 positioned in between.

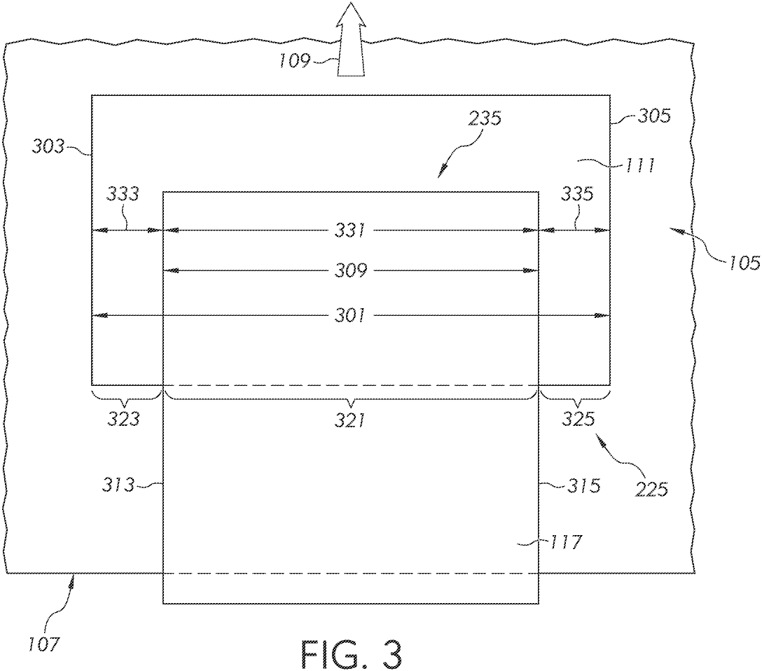

Referring to FIG. 3, a top-down view of the first end 235 of the first electrically-conductive trace 117 overlapping the second end 225 of the electrically-conductive feed line 111 taken along line 3-3 of FIG. 2 is illustrated. In some embodiments, a width of the first electrically-conductive trace 117 and a width of the electrically-conductive feed line 111 may be different. For example, the width dimension of the first electrically-conductive trace 117 and the electrically-conductive feed line 111 can be measured along a direction that may be parallel to the first major surface 105 and parallel to the edge surface 107 to which the first electrically-conductive trace 117 is attached and extends around.

In some embodiments, the second end 225 of the electrically-conductive feed line 111 can comprise a first width 301. For example, the first width 301 can be measured between a first edge 303 of the electrically-conductivefeedline 111 and a second edge 305 of the electrically-conductive feed line 111. In some embodiments, the first edge 303 and the second edge 305 can form the lateral boundaries of the electrically-conductive feed line 111 extending between the opto-electronic device 109 and the first electrically-conductive trace 117. In some embodiments, a distance separating the first edge 303 and the second edge 305 can be substantially constant along a length of the electrically-conductive feed line 111 between the opto-electronic device 109 and the first electrically-conductive trace 117. When the distance separating the first edge 303 and the second edge 305 is substantially constant, the electrically-conductive feed line 111 can comprise a substantially constant first width 301. In some embodiments, the first width 301 can represent a width of the electrically-conductive feed line 111 at the second end 225, with the first width 301 measured adjacent to the second end 225.

In some embodiments, the first end 235 of the first electrically-conductive trace 117 can comprise a second width 309 that may be less than or equal to the first width 301. For example, the second width 309 can be measured between a first edge 313 of the first electrically-conductive trace 117 and a second edge 315 of the first electrically-conductive trace 117. In some embodiments, the first edge 313 and the second edge 315 can form the lateral boundaries of the first electrically-conductive trace 117 extending between the electrically-conductive feed line 111 on the first major surface 105 and the second electrically-conductive feed line 227 (e.g., illustrated in FIG. 2) on the second major surface 201. In some embodiments, a distance separating the first edge 313 and the second edge 315 can be substantially constant along a length of the first electrically-conductive trace 117 between the electrically-conductive feed line 111 and the second electrically-conductive feed line 227. When the distance separating the first edge 313 and the second edge 315 is substantially constant, the first electrically -conductive trace 117 can comprise a substantially constant second width 309. In some embodiments, the second width 309 can represent a width of the first electrically-conductive trace 117 at the first end 235, with the second width 309 measured adjacent to the first end 235. As such, the first width 301 and the second width 309 can represent the respective widths of the electrically-conductive feed line 111 and the first electrically-conductive trace 117 at a location where the first electrically-conductive trace 117 overlaps the electrically-conductive feed line 111.

In some embodiments, one or more portions of the electrically-conductive feed line 111 may be covered by the first electrically-conductive trace 117 while one or more portions of the electrically-conductive feed line 111 may be uncovered by the first electrically-conductive trace 117. For example, in some embodiments, a first portion 321 of the second end 225 of the electrically-conductive feed line 111 may be covered by the first end 235 of the first electrically-conductive trace 117. In some embodiments, a second portion 323 of the second end 225 of the electrically-conductive feed line 111 may be uncovered. In some embodiments, a third portion 325 of the second end 225 of the electrically-conductive feed line 111 may be uncovered. For example, in some embodiments, the first portion 321 can comprise a central portion of the second end 225 of the electrically-conductive feed line 111, with the first portion 321 located a distance from the first edge 303 and a distance from the second edge 305. The distance separating the first portion 321 from the first edge 303 may be the same as or different than the distance separating the first portion 321 from the second edge 305. In some embodiments, the first electrically-conductive trace 117 can overlap and cover the first portion 321, such that an axis that is perpendicular to the first major surface 105 can intersect the first portion 321 of the electrically-conductive feed line 111 and the first end 235 of the first electrically-conductive trace 117. The first portion 321 of the electrically-conductive feed line 111 can therefore be in contact with the first end 235 of the first electrically-conductive trace 117, such that electric current can be conducted between the first portion 321 and the first electrically-conductive trace 117.

In some embodiments, when the second width 309 is less than the first width 301, the second portion 323 and/or the third portion 325 of the electrically-conductive feed line 111 may be uncovered and not in contact with the first electrically-conductive trace 117. For example, the second portion 323 can comprise the portion of the second end 225 of the electrically-conductive feed line 111 that is between the first edge 303 and the first portion 321. In some embodiments, the third portion 325 can comprise the portion of the second end 225 of the electrically-conductive feed line 111 that is between the second edge 305 and the first portion 321. By being uncovered, the first electrically-conductive trace 117 may not overlap the second portion 323 and the third portion 325. For example, when the first electrically-conductive trace 117 does not overlap the second portion 323 (e.g., when the second portion 323 of the second end 225 of the electrically-conductive feed line 111 is uncovered), an axis that is perpendicular to the first major surface 105 can intersect the second portion 323 of the electrically-conductive feed line 111 but does not intersect the first end 235 of the first electrically-conductive trace 117. Similarly, in some embodiments, when the first electrically-conductive trace 117 does not overlap the third portion 325 (e.g., when the third portion 325 of the second end 225 of the electrically-conductive feed line 111 is uncovered), an axis that is perpendicular to the first major surface 105 can intersect the third portion 325 of the electrically-conductive feed line 111 but does not intersect the first end 235 of the first electrically-conductive trace 117.

In some embodiments, the widths of one or more of the first portion 321, the second portion 323, or the third portion 325 may differ. For example, the first portion 321 can comprise a first portion width 331, the second portion 323 can comprise a second portion width 333, and the third portion 325 can comprise a third portion width 335. In embodiments when the second width 309 is equal to the first width 301, the first electrically-conductive trace 117 can substantially match a width-wise dimension of the electrically-conductive feed line 111 such that the second portion width 333 and the third portion width 335 may be zero. In embodiments when the second width 309 is less than the first width 301, the first electrically-conductive trace 117 can differ in a width-wise dimension from the electrically-conductive feed line 111 such that one or both of the second portion width 333 or the third portion width 335 may be non-zero. For example, in some embodiments, (e.g., as illustrated in FIG. 3), the first electrically-conductive trace 117 can be centered relative to the electrically-conductive feed line 111 such that the second portion width 333 may be substantially equal to the third portion width 335. In some embodiments, the first portion width 331 may be greater than the second portion width 333, and the first portion width 331 may be greater than the third portion width 335. By forming the first portion width 331 greater than both the second portion width 333 and the third portion width 335, electric current conductance between the electrically-conductive feed line 111 and the first electrically-conductive trace 117 can be achieved. In some embodiments, the first electrically-conductive trace 117 can also be offset from the center line of the electrically-conductive feed line 111. The first electrically-conductive trace 117 can also overlap one of more edges of the electrically-conductive feed line 111.

In some embodiments, a bulk resistivity of the electrically-conductive feed line 111 may be different than a bulk resistivity of the first electrically-conductive trace 117. For example, based on the materials of the electrically-conductive feed line 111 and the first electrically-conductive trace 117, an electrical conductivity of the electrically-conductive feed line 111 may be greater than an electrical conductivity of the first electrically-conductive trace 117. Electrical conductivity can represent a material’s ability to conduct electric current. Similarly, in these embodiments, an electrical resistivity of the electrically-conductive feed line 111 may be less than an electrical resistivity of the first electrically-conductive trace 117. Electrical resistivity can represent how strongly a material can resist electric current. When the electrically-conductive feed line 111 and the first electrically-conductive trace 117 comprise different materials, the bulk resistivity of the electrically-conductive feed line 111 and the first electrically-conductive trace 117 may be different, as will the electrical conductivity and the electrical resistivity of the electrically-conductive feed line 111 and the first electrically-conductive trace 117.

When the bulk resistivities of the electrically-conductive feed line 111 and the first electrically-conductive trace 117 are mismatched, several benefits may arise from the higher-conductivity material comprising a greater width than the lower-conductivity material. For example, in some embodiments, the electrically-conductivefeedline 111 can comprise a material that has a lower bulk resistivity than the first electrically-conductive trace 117 such that the electrically-conductive feed line 111 may be more electrically-conductive than the first electrically-conductive trace 117. In some embodiments, electrical current crowding (e.g., current crowding effect) can occur at a junction or contact location between two materials that comprise differing bulk resistivities. Current crowding can comprise a non-homogenous distribution of electrical current density between the two materials. For example, the current density at one location at a junction between two materials may differ from the current density at another location at the junction between the two materials. As a result, current crowding can occur when the current density at a location (e.g., between the electrically-conductive feed line 111 and the first electrically-conductive trace 117) is greater than an average current density between the electrically-conductive feed line 111 and the first electrically-conductive trace 117. For example, a high (e.g., greater than an average current density) electrical current density may occur in a localized area.

In some embodiments, due to the second width 309 being less than or equal to the first width 301, the effect of current crowding between the electrically-conductive feed line 111 and the first electrically-conductive trace 117 may be reduced. For example, when the materials of the electrically-conductive feed line 111 and the first electrically-conductive trace 117 are different and the widths (e.g., the first width 301 and the second width 309) are not equal, then the possibility of current crowding may arise. However, the effects of current crowding may be more pronounced when the first width 301 of the first electrically-conductive trace 117 is less than the second width 309 of the electrically-conductive feed line 111 due, in part, to the electrically-conductive feed line 111 comprising a lower bulk resistivity than the first electrically-conductive trace 117. However, when the second width 309 of the electrically-conductive feed line 111 is greater than or equal to the first width 301 of the first electrically-conductive trace 117, the likelihood of current crowding can be reduced. As a result, a constant or near-constant current density between the first electrically-conductive trace 117 and the electrically-conductive feed line 111 can be achieved without areas of localized high current density.

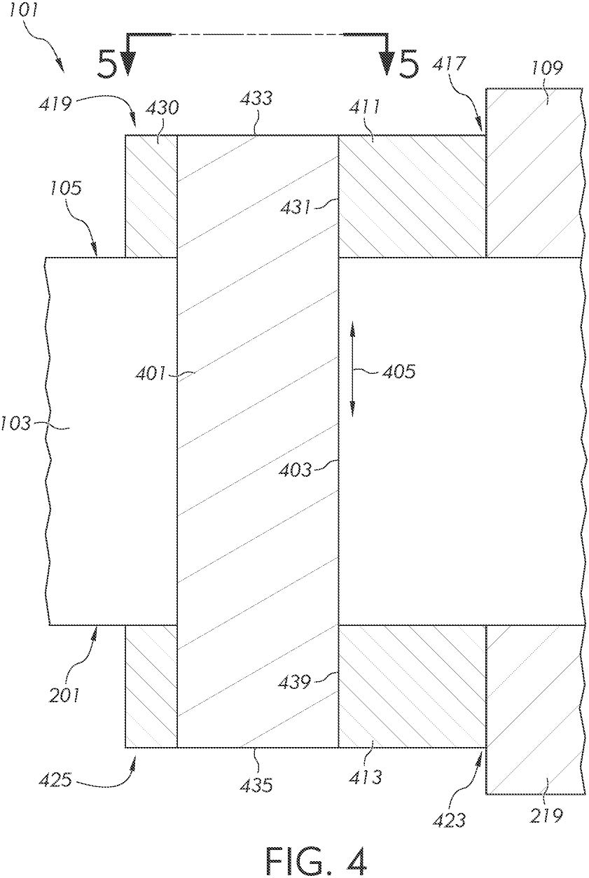

FIG. 4 illustrates a sectional view of the electronic apparatus 101 along line 4-4 of FIG. 1. In some embodiments, the electronic apparatus 101 can comprise a second electrically-conductive trace 401 that can extend through an opening 403 (e.g., a “via”) in the substrate 103 between the first major surface 105 and the second major surface 201. The second electrically-conductive trace 401 can electrically connect a second portion of the opto-electronic device 109 to the electrical component 219 and can define a second current path 405 that may be different than the first current path 239 (e.g., illustrated in FIG. 2). For example, the second current path 405 (e.g., illustrated schematically in FIG. 4 with an arrow) can represent a path through which electric current can travel between the opto-electronic device 109 and the electrical component 219. In some embodiments, the second current path 405 may differ from the first current path 239. For example, the second current path 405 can be through the opening 403 in the substrate 103 between the first major surface 105 and the second major surface 201, while the first current path 239 can be around the edge surface 107 between the first major surface 105 and the second major surface 201. In some embodiments, the second electrically-conductive trace 401 can be similar to the first electrically-conductive trace 117. For example, the second electrically-conductive trace 401 can comprise an electrically-conductive material through which electric current can be conducted. For example, in some embodiments, the second electrically-conductive trace 401 can comprise a conductive metal, such as one or more of aluminum (Al), copper (Cu), gold (Au), nickel (Ni), silver (Ag), titanium (Ti), molybdenum (Mo), or tin (Sn).

In some embodiments, the second electrically-conductive trace 401 can be connected to an electrically-conductive feed line 411 and a second electrically-conductive feed line 413. In some embodiments, the electrically-conductive feed line 411 can be the same as or different than the electrically-conductive feed line 111. For example, as illustrated in FIG. 1, in some embodiments, two, separate electrically-conductive feed lines (e.g., the electrically-conductive feed line 111 and the electrically-conductive feed line 411) can be electrically connected to the opto-electronic device 109, with the electrically-conductive feed line 111 electrically connected to a first portion of the opto-electronic device 109 and the electrically-conductive feed line 411 electrically connected to a second portion of the opto-electronic device 109. In these embodiments, the first electrically-conductive trace 117 can be electrically connected to the electrically-conductive feed line 111, and the second electrically-conductive trace 401 can be electrically connected to the electrically-conductive feed line 411. However, in some embodiments, the electrically-conductive feed line 111 and the electrically-conductive feed line 411 can be the same and can comprise a single electrically-conductive feed line such that one electrically-conductive feed line may be electrically connected to the opto-electronic device 109. In these embodiments, the first electrically-conductive trace 117 and the second electrically-conductive trace 401 can be electrically connected to the same electrically-conductive feed line (e.g., one of the electrically-conductive feed line 111 or the electrically-conductive feed line 411).

In some embodiments, the electrically-conductive feed line 411 can be electrically connected to the opto-electronic device 109 and can be positioned on the first major surface 105. The electrical connection may not be direct, but can go through intermediate electrical elements such as thin film transistors, capacitors, resistors, or other conductor elements. The electrically-conductive feed line 411 can comprise an electrically-conductive material through which electric current can be conducted. For example, in some embodiments, the electrically-conductive feed line 411 can comprise a conductive metal, such as one or more of aluminum (Al), copper (Cu), gold (Au), nickel (Ni), silver (Ag), molybdenum (Mo), indium tin oxide (ITO), titania (Ti), or tin (Sn) or other materials such as carbon nano-tubes (CNT) and conductive pastes. By being positioned on the first major surface 105, the electrically-conductive feed line 411 may or may notbe in contact with the firstmajor surface 105. For example, in some embodiments, the electrically-conductive feed line 411 may be directly connected to and in contact with the first major surface 105. In some embodiments, the electrically-conductive feed line 411 may not be in contact with the first major surface 105 while still being connected to the first major surface 105, for example, with one or more intervening layers or structures between the electrically-conductive feed line 411 and the first major surface 105 (e.g., conductive materials, dielectric materials, semiconductor materials, solder balls, etc.).

In some embodiments, the electrically-conductive feed line 411 can extend between a first end 417 that may be electrically connected to the opto-electronic device 109 and a second end 419. For example, the first end 417 can be electrically connected to the opto-electronic device 109 such that the electrically-conductive feed line 411 can conduct electric current to and/or from the opto-electronic device 109. In some embodiments, the electrically-conductive feed line 411 can transmit data signals to the opto-electronic device 109 such that the data signals can control the operation of the opto-electronic device 109. In some embodiments, the electrically-conductive feed line 411 can transmit power to the opto-electronic device 109 such that the opto-electronic device 109 can be powered through the electrically-conductive feed line 411. In some embodiments, the electrically-conductive feedline 411 can be electrically connectedto a plurality of opto-electronic devices (e.g., more than one of the opto-electronic device 109) such that the data signals and/or power can be transmitted to the plurality of opto-electronic devices.

In some embodiments, the second electrically-conductive feed line 413 can be the same as or different than the second electrically-conductive feed line 227. For example, in some embodiments, two separate second electrically-conductive feed lines (e.g., the second electrically-conductive feed line 227 and the second electrically-conductive feed line 413) can be electrically connected to the electrical component. In these embodiments, the first electrically-conductive trace 117 can be electrically connected to the second electrically-conductive feed line 227 and the second electrically-conductive trace 401 can be electrically connected to the second electrically-conductive feed line 413. However, in some embodiments, the second electrically-conductive feed line 227 and the second electrically-conductive feed line 413 can be the same and can comprise a single, second electrically-conductive feed line such that one second electrically-conductive feed line may be electrically connected to the electrical component 219. In these embodiments, the first electrically-conductive trace 117 and the second electrically-conductive trace 401 can be electrically connected to the same second electrically-conductive feed line (e.g., one of the second electrically-conductive feed line 227 or the second electrically-conductive feed line 413).

In some embodiments, the second electrically-conductive feed line 413 can be electrically connected to the electrical component 219. For example, the second electrically-conductive feed line 413 can be positioned on the second major surface 201. The second electrically-conductive feed line 413 can comprise an electrically-conductive material through which electric current can be conducted. For example, in some embodiments, the second electrically-conductive feed line 413 can be similar to the second electrically-conductive feed line 227 and can comprise a conductive metal, such as one or more of aluminum (Al), copper (Cu), gold (Au), nickel (Ni), silver (Ag), molybdenum (Mo), indium tin oxide (ITO), titania (Ti), or tin (Sn) or other materials such as carbon nano-tubes (CNT) and conductivepastes. By being positioned on the second major surface 201, the second electrically-conductive feed line 413 may or may not be in contact with the second major surface 201. For example, in some embodiments, the second electrically-conductive feed line 413 may be directly connectedto and in contact with the second major surface 201. In some embodiments, the electrically-conductive feed line 111 may not be in contact with the second major surface 201 while still being connected to the second major surface 201, for example, with one or more intervening layers or structures between the second electrically-conductive feed line 413 and the second major surface 201 (e.g., conductive materials, dielectric materials, semiconductor materials, solder balls, etc.).

In some embodiments, the second electrically-conductive feed line 413 can extend between a first end 423 that may be electrically connected to the electrical component 219 and a second end 425. For example, the first end 423 can be electrically connected to the electrical component 219 such that the second electrically-conductivefeed line 413 can conduct electric current to and/or from the electrical component 219. In some embodiments, the second electrically-conductive feed line 413 can transmit data signals from the electrical component 219 and to the opto-electronic device 109 such that the data signals can control the operation of the opto-electronic device 109. In some embodiments, the second electrically-conductive feed line 413 can transmit power from the electrical component 219 and to the opto-electronic device 109 such that the opto-electronic device 109 can be powered through the second electrically-conductive feed line 413. In some embodiments, the second electrically-conductive feed line 413 can be electrically connected to a plurality of electrical components (e.g., more than one of the electrical component 219) such that the data signals and/or power can be transmitted to one or more of the opto-electronic devices.

In some embodiments, the second electrically-conductive trace 401 can extend through the opening 403 in the substrate 103 between the first major surface 105 and the second major surface 201 and a second opening 431 in the second end 419 of the electrically-conductive feed line 411. In some embodiments, the openings 403, 431, and 439 can differ in diameter, size, and/or shape. Also, the openings 403, 431, and 439 can vary in cross-section through the depths of the openings 403, 431, and 439, for example, the openings 403, 431, and 439 can comprise non-linear and complex sidewall shapes. In some embodiments, for example, the second opening 431 can extend partially or completely through the second opening 431 in the second end 419 of the electrically-conductive feed line 411. In some embodiments, the second electrically-conductive trace 401 can extend between a first end 433 that is received within the second opening 431 of the electrically-conductive feed line 411 and a second end 435 that is electrically connected to the electrical component 219. In some embodiments, the second electrically-conductive feed line 413 can comprise a third opening 439 through which the second end 435 of the second electrically-conductive trace 401 can extend. For example, the second electrically-conductive trace 401 can extend partially or completely through the third opening 439 in the second end 425 of the second electrically-conductive feed line 413. In some embodiments, the second electrically-conductive trace 401 may not completely fill the openings 403, 431, and 439.

In some embodiments, the second electrically-conductive trace 401 can be electrically connected to the electrically-conductive feed line 411 and to the second electrically-conductive feed line 413. For example, the first end 433 of the second electrically-conductive trace 401 can be in contact with the wall 430 of the electrically-conductive feed line 411 that surrounds the second opening 431. In some embodiments, the second end 435 of the second electrically-conductive trace 401 can be in contact with the wall 430 of the second electrically-conductive feed line 413 that surrounds the third opening 439. In some embodiments, by being electrically connected to the second electrically-conductive feed line 413, the second electrically-conductive trace 401 can receive electric current from the second electrically-conductive feed line 413, whereupon the second electrically-conductive trace 401 can deliver the electric current to the electrically-conductive feed line 411.

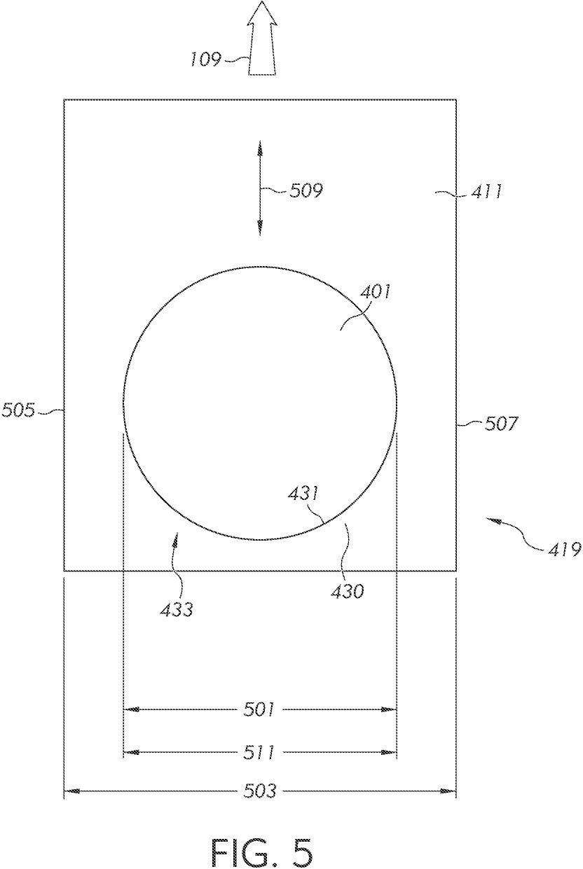

Referring to FIG. 5, a top-down view of the first end 433 of the second electrically-conductive trace 401 received within the second opening 431 of the electrically-conductive feed line 411 as viewed along line 5-5 of FIG. 4 is illustrated. In some embodiments, the first end 433 of the second electrically-conductive trace 401 can comprise a diameter 501 that may be less than a first width 503 of the electrically-conductive feed line 411. For example, in some embodiments, the first width 503 can be measured between a first edge 505 of the electrically-conductive feed line 411 and a second edge 507 of the electrically-conductive feed line 411. In some embodiments, the first edge 505 and the second edge 507 can form lateral boundaries of the electrically-conductive feed line 411 extending between the first end 417 (e.g., illustrated in FIG. 4) at the opto-electronic device 109 and the second end 419. In some embodiments, a distance separating the first edge 505 and the second edge 507 can be substantially constant along a length of the electrically-conductive feed line 411 between the first end 417 and the second end 419. In some embodiments, the first width 503 can represent a width of the electrically-conductive feed line 411 at the second end 419. For example, the first width 503 can be measured along an axis that may be perpendicular to the first edge 505 and the second edge 507 and perpendicular to a direction 509 along which the electrically-conductive feed line 411 extends between the first end 417 and the second end 419.

In some embodiments, due to the diameter 501 being less than the first width 503, the first end 433 of the second electrically-conductive trace can be surrounded by the second end 419 of the electrically-conductive feed line 411. For example, the first end 433 can be completely surrounded and bordered by the wall 430 of the second electrically-conductive trace 401 that borders the second opening 431. For example, in some embodiments, the second opening 431 can comprise an opening diameter 511 that substantially matches the diameter 501 of the second electrically-conductive trace 401. In this way, at least a majority of the perimeter of the first end 433 of the second electrically-conductive trace 401 can be in contact with the wall 430 that defines the second opening 431. By being surrounded by, the first end 433 can be bordered by the wall 430 such that all portions of the first end 433 that define the diameter 501 are bordered by the wall 430.

In some embodiments, a bulk resistivity of the electrically-conductive feed line 411 may be different than a bulk resistivity of the second electrically-conductive trace 401. For example, similar to the embodiments described relative to FIGS. 1-3, based on the materials of the electrically-conductive feed line 411 and the second electrically-conductive trace 401, an electrical conductivity of the electrically-conductive feed line 411 may be different than an electrical conductivity of the second electrically-conductive trace 401. To facilitate the transfer of electric current between the electrically-conductive feed line 411 and the second electrically-conductive trace 401 and reduce the likelihood of electrical current crowding, the diameter 501 of the second electrically-conductive trace 401 may be less than the first width 503 of the electrically-conductive feed line 411 such that the second electrically-conductive trace 401 may be surrounded by the electrically-conductive feed line 411.

In some embodiments, the second electrically-conductive trace 401 may be well-suited for transmitting power between the electrical component 219 and the opto-electronic device 109. For example, as compared to the first electrically-conductive trace 117, in some embodiments, a first cross-sectional area of the first electrically-conductive trace 117 (e.g., illustrated in FIGS. 2-3) may be less than a second cross-sectional area of the second electrically-conductive trace 401. For example, the first cross-sectional area of the first electrically-conductive trace 117 can be represented by a height 512 (e.g., illustrated in FIG. 2) of the first electrically-conductive trace 117 multiplied by the second width 309 (e.g., illustrated in FIG. 2) of the first electrically-conductive trace 117. The second cross-sectional area of the second electrically-conductive trace 401 can be represented by (π ^{∗} r²), wherein r is half of the diameter 501 for the case where the opening is fully-filled. The second cross-sectional area of the second electrically conductive trace 401 can be represented by (π * r² -π * z²), wherein z is (r - the conductor thickness) for the case where the opening is partially-filled. In some embodiments, due to the second electrically-conductive trace 401 comprising the second cross-sectional area that is greater than the first cross-sectional area of the first electrically-conductive trace 117 in combination with the difference in bulk conductivities of the materials, the second electrically-conductive trace 401 can comprise a lower impedance than the first electrically-conductive trace 117. The impedance is the measure of the opposition that an electrically-conductive trace presents to an electric current when a voltage is applied (e.g, an amount of opposition that an electrically-conductivetrace presents to a change in current or voltage).

Due to the second electrically-conductive trace 401 comprising the lower impedance, the second electrically-conductive trace 401 can accommodate higher electrical requirements for power transmission or ground lines. For example, when power is transmitted through an electrically-conductive trace from the electrical component 219 to the opto-electronic device 109, the electrically-conductive trace may carry higher electrical current at a lower frequency. When data signals are transmitted through an electrically-conductive trace from the electrical component 219 to the opto-electronic device 109, the first electrically-conductive trace may carry lower current at a higher frequency. Accordingly, in some embodiments, several benefits arise from the electronic apparatus 101 comprising electrically-conductive traces of varying cross-sectional areas. For example, in some embodiments, some of the electrically-conductive traces can comprise smaller cross-sectional areas, such as the first electrically-conductive trace 117 that comprises the first cross-sectional area, that may be better suited for transmitting data signals (of a lower current and higher frequency) to the opto-electronic device 109. Similarly, in some embodiments, some of the electrically-conductive traces can comprise larger cross-sectional areas, such as the second electrically-conductive trace 401 that comprises the second cross-sectional area, that may be better suited for transmitting power (of a higher current and lower frequency) to the opto-electronic device 109. Accordingly, instead of all of the electrically-conductive traces comprising the same dimensions and cross-sectional areas, the electronic apparatus 101 can provide the first electrically-conductive trace 117, which may be well-suited for transmitting data signals, and the second electrically-conductivetrace 401, which may be well-suited for transmitting power. Alternatively, in some embodiments, the electronic apparatus 101 may comprise multiple first electrically-conductive traces 117 structures that vary in cross-sectional area, width, and spacing between them. For example, multiple first electrically-conductive traces 117 may be separated by varying spacing along the perimeter of substrate 103. Alternatively, the electronic apparatus 101 may comprise multiple second electrically-conductive traces 401 that vary in cross-sectional area. In addition, the smaller first cross-sectional area of the first electrically-conductive trace 117 can occupy less space than the larger second cross-sectional area of the second electrically-conductivetrace 401, which can increase the layout efficiency of the electronic apparatus 101 by increasing the available space on the substrate 103. In some embodiments, the electrically-conductive traces (compered edge -electrode vs edge electrode, via vs via, or edge electrode vs via) can differ in cross-sectional area by greater than about 5%, greater than about 10%, greater than about 50%, greater than about 100%, or greater than about 200%. In some embodiments, the second electrically-conductive trace 401 can be located at a distance inward from the edge surface 107 (e.g., in contrast to the first electrically-conductive trace 117 that may be wrapped around the edge surface 107), thus providing a shorter length of the second electrically-conductive trace 401 and less power loss.

The electronic apparatus 101 can provide several benefits. For example, in some embodiments, the electronic apparatus 101 can comprise a plurality of electrically-conductive traces, for example, the first electrically-conductive trace 117 and the second electrically-conductive trace 401. Due to the differing cross-sectional areas of the electrically-conductive traces, the first electrically-conductive trace 117 can transmit data signals to the opto-electronic device 109 and the second electrically-conductive trace 401 can transmit power to the opto-electronic device 109. Alternatively, a larger first electrically-conductive trace 117 can transmit power and a smaller first electrically-conductive trace 117 can transmit data signals. The relatively smaller first electrically-conductive trace 117 can therefore occupy less space while wrapping around the edge surface 107, thus affording more space for other structures on the substrate 103. Further, in some embodiments, the first electrically-conductive trace 117 can overlap the electrically-conductive feed line 111. Despite comprising different materials and due to the first electrically-conductive trace 117 comprising a smaller width than the electrically-conductive feed line 111, the likelihood of current crowding between the first electrically-conductive trace 117 and the electrically-conductive feed line 111 may be reduced. In addition, the non-planar shape of the edge surface 107 can allow for the first electrically-conductive trace 117 to comprise a shorter length between the opto-electronic device 109 and the electrical component 219. The shorter length can reduce the electrical resistance of the first electrically-conductive trace 117.

It should be understood that while various embodiments have been described in detail relative to certain illustrative and specific examples thereof, the present disclosure should not be considered limited to such, as numerous modifications and combinations of the disclosed features are possible without departing from the scope of the following claims.

1. An electronic apparatus comprising:
a substrate comprising a first major surface, a second major surface, and an edge surface extending between the first major surface and the second major surface, the edge surface comprising a radius of curvature extending between the first major surface and the second major surface;
an opto-electronic device positioned on the first major surface;
an electrical component positioned on the second major surface;
a first electrically-conductive trace attached to the edge surface and extending between the first major surface and the second major surface, the first electrically-conductive trace electrically connecting a first portion of the opto-electronic device to the electrical component and defining a first current path; and
a second electrically-conductive trace extending through an opening in the substrate between the first major surface and the second major surface, the second electrically-conductive trace electrically connecting a second portion of the opto-electronic device to the electrical component and defining a second current path different than the first current path.

2. The electronic apparatus of claim 1, further comprising an electrically-conductive feed line extending between a first end electrically connected to the opto-electronic device and a second end comprising a first width.

3. The electronic apparatus of claim 2, wherein the first electrically-conductive trace extends between a first end electrically connected to the electrically-conductive feed line and a second end electrically connected to the electrical component.

4. The electronic apparatus of claim 3, wherein the first end of the first electrically-conductive trace overlaps the second end of the electrically-conductive feed line such that the second end of the electrically-conductive feed line is positioned between the substrate and the first end of the first electrically-conductive trace, the first end of the first electrically-conductive trace comprising a second width less than or equal to the first width.

5. The electronic apparatus of claim 2, wherein the second electrically-conductive trace extends through a second opening in the second end of the electrically-conductive feed line.

6. The electronic apparatus of claim 5, wherein the second electrically-conductive trace extends between a first end received within the second opening of the electrically-conductive feed line and a second end electrically connected to the electrical component.

7. The electronic apparatus of claim 6, wherein the first end of the second electrically-conductive trace comprises a diameter less than the first width.

8. The electronic apparatus of claim 1, wherein a first cross-sectional area of the first electrically-conductive trace is less than a second cross-sectional area of the second electrically-conductive trace.

9. The electronic apparatus of claim 8, wherein an impedance of the second electrically-conductive trace is less than an impedance of the first electrically-conductive trace.

10. The electronic apparatus of claim 1, wherein the opto-electronic device comprises a micro light-emitting diode.

11. The electronic apparatus of claim 1, wherein the substrate is one or more of soda-lime glass, borosilicate glass, alumino -borosilicate glass, alkali-containing glass, alkali-free glass, aluminosilicate, borosilicate, boroaluminosilicate, silicate, or glass-ceramic.

12. The electronic apparatus of claim 1, wherein the radius of curvature is less than 100 micrometers.

13. An electronic apparatus comprising:
a substrate comprising a first major surface, a second major surface, and an edge surface extending between the first major surface and the second major surface, the edge surface comprising a radius of curvature extending between the first major surface and the second major surface;
an opto-electronic device positioned on the first major surface;
an electrical component positioned on the second major surface;
an electrically-conductive feed line extending between a first end electrically connected to the opto-electronic device and a second end comprising a first width; and
a first electrically-conductive trace attached to the edge surface and extending between the first major surface and the second major surface, the first electrically-conductive trace extending between a first end electrically connected to the electrically-conductive feed line and a second end electrically connected to the electrical component, the first end of the first electrically-conductive trace overlapping the second end of the electrically-conductive feed line such that the second end of the electrically-conductive feed line is positioned between the substrate and the first end of the first electrically-conductive trace, the first end of the first electrically-conductive trace comprising a second width less than or equal to the first width.

14. The electronic apparatus of claim 13, wherein a bulk resistivity of the electrically-conductive feed line is different than a bulk resistivity of the first electrically-conductive trace.

15. The electronic apparatus of claim 13, wherein the radius of curvature comprises a first radius of curvature between the first major surface and the edge surface.

16. The electronic apparatus of claim 15, wherein the radius of curvature comprises a second radius of curvature between the second major surface and the edge surface.

17. The electronic apparatus of claim 13, wherein a first portion of the second end of the electrically-conductive feed line is covered by the first end of the first electrically-conductive trace, and a second portion of the second end of the electrically-conductive feed line is uncovered.

18. The electronic apparatus of claim 13, wherein the opto-electronic device comprising a micro light-emitting diode.

19. An electronic apparatus comprising:
a substrate comprising a first major surface, a second major surface, and an edge surface extending between the first major surface and the second major surface, the edge surface comprising a radius of curvature extending between the first major surface and the second major surface;
an opto-electronic device positioned on the first major surface;
an electrical component positioned on the second major surface;
an electrically-conductive feed line extending between a first end electrically connected to the opto-electronic device and a second end comprising a first width; and
a second electrically-conductive trace extending through an opening in the substrate between the first major surface and the second major surface and a second opening in the second end of the electrically-conductive feed line, the second electrically-conductive trace extending between a first end received within the second opening of the electrically-conductive feed line and a second end electrically connected to the electrical component, the first end of the second electrically-conductive trace comprising a diameter less than the first width.

20. The electronic apparatus of claim 19, wherein the first end of the second electrically-conductive trace is surrounded by the second end of the electrically-conductive feed line.

21. The electronic apparatus of claim 19, wherein a bulk resistivity of the electrically-conductive feed line is different than a bulk resistivity of the second electrically-conductive trace.

22. The electronic apparatus of claim 19, wherein the opto-electronic device comprises a micro light-emitting diode.
